(19) United States
(12) Patent Application Publication
(10) Pub. No.: US 2022/0035211 A1
(43) Pub. Date: Feb. 3, 2022

(54) DISPLAY PANEL AND DISPLAY DEVICE

(71) Applicants: BEIHAI HKC OPTOELECTRONICS TECHNOLOGY CO., LTD., Guangxi (CN); Chuzhou HKC Optoelectronics Technology Co., Ltd., Anhui (CN)

(72) Inventors: Guangjia WANG, Anhui (CN); Shishuai HUANG, Anhui (CN)

(21) Appl. No.: 17/299,224

(22) PCT Filed: Jun. 10, 2020
(86) PCT No.: PCT/CN2020/095360

§ 371 Date: Jun. 2, 2021

(30) Foreign Application Priority Data
Jun. 10, 2019 (CN) 201910495837.0

(51) Int. Cl. G02F 1/1362; H01L 27/12

(52) U.S. Cl. CPC G02F 1/136222; H01L 27/1218; G02F 1/136286

(57) ABSTRACT

A display panel comprises: an array substrate on which common wiring is provided; a color filter substrate cell-assembled with the array substrate, a common electrode corresponding to the common wiring being provided on the color filter substrate; a sealant disposed between the array and filter substrates, and enclosing a liquid crystal accommodating space with the array and filter substrates; and a conductive glue ball embedded in the sealant and used for conducting the wiring of the array substrate and the electrode of the filter substrate. The non-display region of the array substrate comprises a transfer region corresponding to the position of the glue ball and a surrounding region disposed around the transfer region; taking the surface of the array substrate distant from the filter substrate as a reference, the height of the surrounding region of the array substrate is less than the maximum height of the transfer region of the array substrate.

### CROSS-REFERENCE TO RELATED APPLICATIONS

This application claims priority to Chinese Patent Applications No. 2019104958370, filed on Jun. 10, 2019, entitled “DISPLAY PANEL AND DISPLAY DEVICE”, and the entire content of which is incorporated herein by reference for all purposes.

### TECHNICAL FIELD

The present disclosure relates to a display field, and in particular, to a display panel and a display device.

### BACKGROUND

This section provides background information related to the present disclosure which is not necessarily prior art.

In a vertical alignment (VA, vertical alignment technology) type display panel, liquid crystals are driven by an electric field between a color filter substrate and an array substrate. A transition area is provided on the array substrate at an appropriate position. The transition area is provided with a first metal layer for transmitting a common electrode signal and a transparent conductive layer electrically connected to the first metal layer thereon. In a working process, the electrode signal on a common wiring of the array substrate can be transmitted to a common electrode of the color filter substrate through the transparent conductive layer on the transition area and a conductive rubber ball provided on the transition area.

However, during a manufacturing process of the display panel, it is easy to cause the conductive rubber ball to deviate from the transition area, resulting in light leakage.

### SUMMARY

According to various embodiments, a display panel is provided.

A display panel includes:
an array substrate provided with a common wiring thereon;
a color filter substrate aligned with the array substrate, and the color filter substrate being provided with a common electrode thereon corresponding to the common wiring;
a sealant provided between the array substrate and the color filter substrate, and the sealant, the array substrate and the color filter substrate enclosing a liquid crystal accommodating space; and
a conductive rubber ball embedded in the sealant to conduct the common wiring of the array substrate to the common electrode of the color filter substrate.

The non-display area of the array substrate includes a transition area corresponding to the conductive rubber ball and a surrounding area surrounding the transition area. Taking a surface of the array substrate away from the color filter substrate as a reference, a height of the surrounding area of the array substrate is less than the maximum height of the transition area of the array substrate.

In the above display panel, the height of the surrounding area of the array substrate is less than the maximum height of the transition area of the array substrate, and thus even if the conductive rubber ball deviates from the transition area, the distance between the array substrate and the color filter substrate is not increased, thereby avoiding light leakage.

A display device includes the display panel as described above.

In the above display device, the height of the surrounding area of the array substrate is less than the maximum height of the transition area of the array substrate, thus even if the conductive rubber ball deviates from the transition area, the distance between the array substrate and the color filter substrate is not increased, thereby avoiding light leakage.

### BRIEF DESCRIPTION OF THE DRAWINGS

In order to better describe and illustrate embodiments and/or examples of these things disclosed herein, reference may be made to one or more drawings. Additional details or examples used to describe the drawings should not be considered as a limitation on the scope of any of the disclosed things, the currently described embodiments and/or examples, and the best modes of these things currently understood.

FIG. 1 is a top view of a display panel according to an embodiment.

FIG. 2 is a partial enlarged cross-sectional view taken along a line M-M in FIG. 1.

FIG. 3 is a partial enlarged cross-sectional view of a display panel according to another embodiment.

FIG. 4 is a partial enlarged cross-sectional view of a display panel according to another embodiment.

FIG. 5 is a partial enlarged cross-sectional view of a display panel according to another embodiment.

FIG. 6 is a partial enlarged cross-sectional view of a display panel according to another embodiment.

FIG. 7 is a partial enlarged cross-sectional view of a display panel according to another embodiment.

FIG. 8 is a partial enlarged cross-sectional view of a display panel according to another embodiment.

### DETAILED DESCRIPTION OF THE EMBODIMENTS

The above objects, features and advantages of the present application will become more apparent by describing in detail embodiments thereof with reference to the accompanying drawings. Though the above embodiments have been particularly described in details, they may only represent several modes of implementation, and cannot be construed as limiting the scope of the present application. It should be understood by those skilled in the art that a plurality of modification and improvement may be made therein without departing from the spirit of the present application. Therefore, the scope of protection of the present application shall be subject to the appended claims.

It will be understood that when an element is referred to as being “fixed on” another element, it can be directly on another element or intervening elements may be present therebetween. When an element is referred to as being “connected” or “coupled” to another element, it can be directly connected or coupled to the other element or intervening elements may be present therebetween.

Unless otherwise defined, all terms (including technical and scientific terms) used herein have the same meaning as commonly understood by one of ordinary skill in the art to which this application belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. As used herein, the term “and/or” includes any and all combinations of one or more of the associated listed items.

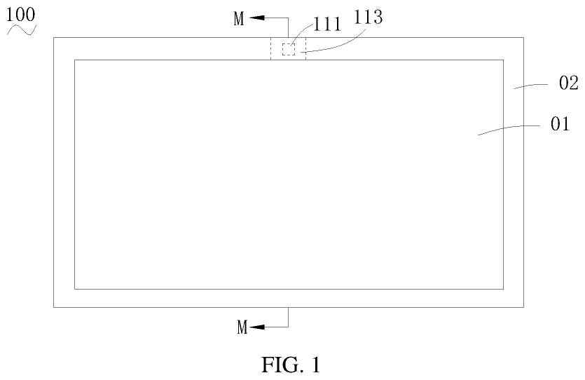

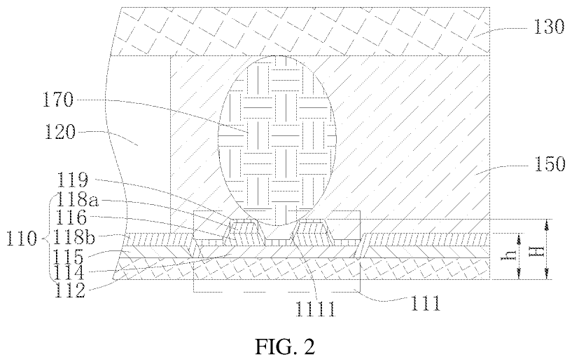

As shown in FIGS. 1 and 2, a display panel 100 according to an embodiment includes an array substrate 110, a color filter substrate 130 aligned with the array substrate 110, a sealant 150, and a conductive rubber ball 170.

A common wiring is provided on the array substrate 110. A common electrode corresponding to the common wiring is provided on the color filter substrate 130. The sealant 150 is provided between the array substrate 110 and the color filter substrate 130. The sealant 150, the array substrate 110, and the color filter substrate 130 enclose a liquid crystal accommodating space 120. The conductive rubber ball 170 is embedded in the sealant 150 to conduct the common wiring of the array substrate 110 to the common electrode of the color filter substrate 130.

The array substrate 110 includes a display area 01 and a non-display area 02 surrounding the display area 01. The non-display area 02 includes a transition area 111 corresponding to the conductive rubber ball 170 and a surrounding area 113 surrounding the transition area 111. Taking a surface of the array substrate 110 away from the color filter substrate 130 as a reference, a height h of the surrounding area 113 of the array substrate 110 is less than the maximum height H of the transition area 111 of the array substrate 110.

The display panel 100 shown in FIG. 1 has a rectangular shape. It should be understood that, in other feasible embodiments, the display panel 100 is not limited to a rectangular shape, and may also have a regular shape such as a circle or an irregular shape.

It should be noted that a boundary between the transition area 111 and the surrounding area 113 cannot be directly seen at a top view angle shown in FIG. 1. The boundary between the transition area 111 and the surrounding area 113 is schematically indicated by dotted lines in FIG. 1.

FIG. 1 only schematically shows positions of one transition area 111 and one surrounding area 113. In the practical structure, the non-display area of the array substrate 110 is provided with a plurality of transition areas 111 and a plurality of surrounding areas 113 corresponding to each transition area 111.

In this embodiment, the transition area 111 schematically shown in FIG. 1 is located in a middle position of the array substrate 110 at a corresponding side. It should be understood that, in other feasible embodiments, the positions of the transition area 111 can be reasonably arranged according to the size of the display panel and the number of conductive rubber balls required.

In the display panel 100, since the height h of the surrounding area 113 of the array substrate 110 is less than the maximum height H of the transition area 111 of the array substrate 110, even if the conductive rubber ball 170 deviates from the transition area 111, a distance between the array substrate 110 and the color filter substrates 130 is not increased, thereby avoiding light leakage.

It is to be understood that liquid crystals are provided in the liquid crystal accommodating space 120, which can be implemented by conventional means in the art, and will not be repeated here.

Specifically, referring to FIG. 2, in this embodiment, the transition area 111 of the array substrate 110 includes a substrate 112, a first metal layer 114 provided on the substrate 112, a first inorganic film layer provided on a part of a surface of the first metal layer 114, and a transparent metal layer 119 provided on the remaining surface of the first metal layer 114 and the first inorganic film layer.

The transparent metal layer 119 is electrically connected to the first metal layer 114. As shown in FIG. 2, in this embodiment, the electrical connection between the transparent metal layer 119 and the first metal layer 114 is implemented by providing a via hole 1111 on the first inorganic film layer deep to the first metal layer 114, and then depositing or attaching the transparent metal layer 119 in the via hole 1111.

It should be noted that a plurality of via holes 1111 are provided on the transition area 111 of each array substrate 110, so as to better achieve the electrical connection between the first metal layer 114 and the transparent metal layer 119. However, only three via holes 1111 are shown schematically in FIG. 2.

In this embodiment, the conductive rubber ball 170 may be a silver rubber ball or a gold rubber ball. It should be understood that the conductive rubber ball 170 is a mixture of elastic colloidal material and conductive metal such as gold or silver. The conductive rubber ball 170 has certain elasticity, and thus when the conductive rubber ball 170 is placed on the transition area 111, the conductive rubber ball 170 can be in surface contact with the transition area 111 of the array substrate 110. Moreover, it should be understood that the contact area between the transition area 111 and the conductive rubber ball 170 corresponds to a plurality of via holes 1111.

In addition, since the conductive rubber ball 170 has elasticity, and a height of the conductive rubber ball 170 in a direction perpendicular to the display panel 100 is slightly greater than the distance between the array substrate 110 and the color filter substrate 130 in a corresponding area, the conductive rubber ball 170 between the array substrate 110 and the color filter substrate 130 is in a compressed state, such that the conductive rubber ball 170 can be more stably provided between the array substrate 110 and the color filter substrate 130.

Since the conductive rubber ball 170 between the array substrate 110 and the color filter substrate 130 is in the compressed state, even if the conductive rubber ball 170 deviates from the transition area 111, both ends of the conductive rubber ball 170 can abut against the common wiring of the array substrate 110 and the common electrode of the color filter substrate 130, such that electrode signal on the common wiring of the array substrate 110 can be transmitted to the common electrode of the color filter substrate 130.

It can be understood that portions located on both sides of the transition area 111 in FIG. 2 are the surrounding area 113. In this embodiment, the surrounding area 113 of the array substrate 110 includes the substrate 112, a second metal layer 115 provided on the substrate 112, and a second inorganic film layer provided on the second metal layer 115. The second metal layer 115 is electrically connected to the first metal layer 114.

It should be noted that the first metal layer 114 and the second metal layer 115 are different metal layers. Specifically, in this embodiment, the first metal layer 114 is a gate layer, and the second metal layer 115 is a source/drain layer. The common wiring of the array substrate 110 is a metal wiring of the source/drain layer. Generally, in order to facilitate a curing of the sealant 150 and the conductive rubber ball 170, the common wiring is hollow.

It can be understood that the first metal layer 114 and gate wiring of the array substrate 110 can be formed simultaneously. Likewise, the second metal layer 115 and the gate/drain wiring of the array substrate 110 can be formed simultaneously.

It should be noted that when the array substrate 110 is in an outer area or under an external force, friction occurs between adjacent film layers in each metal layer and inorganic layer, and thus static electricity is accumulated on the metal layer. In this embodiment, since the first metal layer 114 and the second metal layer 115 are different metal layers on the array substrate 110, and the first metal layer 114 is electrically connected to the second metal layer 115, the static electricity generated on the first metal layer 114 and the second metal layer 115 can be transferred to each other, thereby preventing the electrostatic breakdown phenomenon caused by the large-area static electricity accumulation on the single metal layer.

Specifically, the electrical connection between the first metal layer 114 and the second metal layer 115 can be achieved by a via hole commonly used in the art, or by electrically connecting the transparent metal layer 119 to the first metal layer 114 and the second metal layer 115 simultaneously.

Referring to 2, specifically in this embodiment, the first inorganic film layer includes a dielectric layer 116 (GI layer) provided on the first metal layer 114 and a first passivation layer 118a (PV layer) provided on the dielectric layer 116. The second inorganic film layer includes a second passivation layer 118b provided on the second metal layer 115. A thickness of the first passivation layer 118a is the same as that of the second passivation layer 118b. The first metal layer 114 and the second metal layer 115 are separated by a second passivation layer 118b.

The height h of the surrounding area 113 of the array substrate 110 is less than the maximum height H of the transition area 111 of the array substrate 110. As shown in FIG. 2, the maximum height H of the transition area 111=(a thickness of the substrate 112+a thickness of the first metal layer 114+a thickness of the dielectric layer 116+a thickness of the first passivation layer 118a+a thickness of the transparent metal layer 119).

Compared with the transition area 111 of the array substrate 110, the surrounding area 113 of the array substrate 110 does not have the first metal layer 114, the dielectric layer 116 and the transparent metal layer 119, but has a second metal layer 115. Although a thickness of the second metal layer 115 is generally slightly greater than the thickness of the first metal layer 114, a thickness difference between the second metal layer 115 and the first metal layer 114 is much less than the sum of the thicknesses of the dielectric layer 116 and the transparent metal layer 119. Therefore, the height h of the surrounding area 113 of the array substrate 110 is less than the maximum height H of the transition area 111 of the array substrate 110.

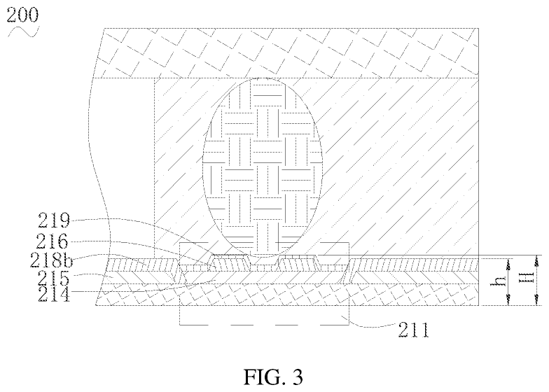

As shown in FIG. 3, a display panel 200 according to another embodiment is substantially the same as the display panel 100, except that the first inorganic film layer only includes a dielectric layer 216.

Compared with a transition area 211 of an array substrate, a surrounding area of the array substrate doer not have a first metal layer 214, a dielectric layer 216, and a transparent metal layer 219, but has a second metal layer 215 and a second passivation layer 218b. Generally, a thickness difference between the second metal layer 215 and the first metal layer 214 is less than a thickness of the transparent metal layer 219, and a thickness of the dielectric layer 216 is generally equal to a second passivation layer 218b, such that a height h of the surrounding area of the array substrate is less than the maximum height H of the transition area 211 of the array substrate.

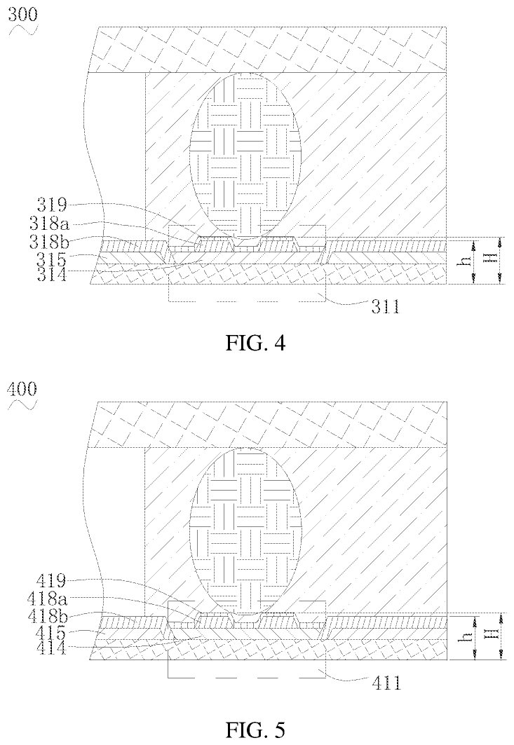

As shown in FIG. 4, a display panel 300 according to another embodiment is substantially the same as the display panel 200, except that the first inorganic film layer only includes a first passivation layer 318a.

Compared with a transition area 311 of an array substrate, a surrounding area of the array substrate doer not have a first metal layer 314 and a transparent metal layer 319, but has a second metal layer 315. Generally, a thickness difference between the second metal layer 315 and the first metal layer 314 is less than a height of the transparent metal layer 319, and thus a height h of the surrounding area of the array substrate is less than the maximum height H of the transition area 311 of the array substrate.

As shown in FIG. 5, a display panel 400 according to another embodiment is substantially the same as the display panel 100, except that the first metal layer 414 is a source/drain layer, and the second metal layer 415 is a gate layer. In this case, the common wiring of an array substrate is a gate metal wiring.

Likewise, the first metal layer 414 and the second metal layer 415 are different metal layers, and the first metal layer 414 is electrically connected to the second metal layer 415, such that electrostatic breakdown phenomenon caused by the large-area static electricity accumulation on the single metal layer can be prevented.

A first inorganic film layer includes a first passivation layer 418a provided on the first metal layer 414. A second inorganic film layer includes a second passivation layer 418b provided on the second metal layer 415.

Compared with a transition area 411 of the array substrate, a surrounding area of the array substrate does not have the first metal layer 414 and a transparent metal layer 419, but has the second metal layer 415. Generally, a thickness of the second metal layer 415 is slightly greater than a thickness of the first metal layer 414, and thus a height h of the surrounding area of the array substrate is less than the maximum height H of the transition area 411 of the array substrate.

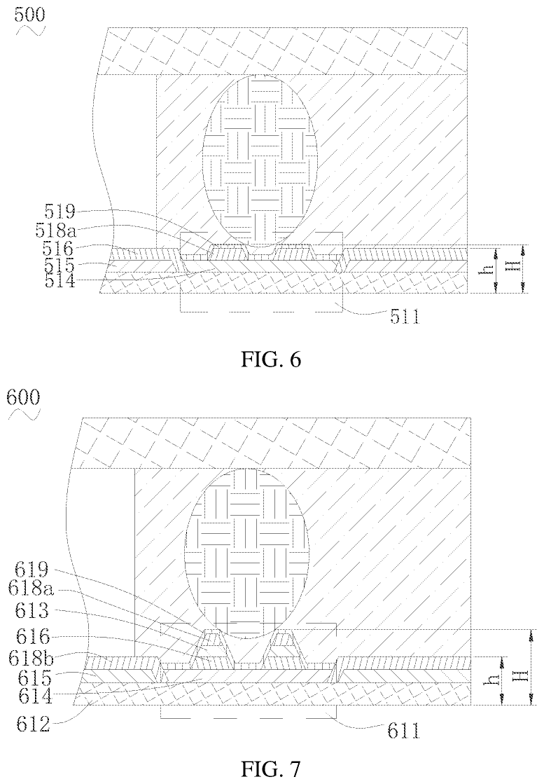

As shown in FIG. 6, a display panel 500 according to another embodiment is substantially the same as the display panel 400, except that the second inorganic film layer includes a dielectric layer 516 provided on a second metal layer 515.

Compared with a transition area 511 of an array substrate, a surrounding area of the array substrate doer not have a first metal layer 514, a first passivation layer 518a and a transparent metal layer 519, but has the second metal layer 515 and the dielectric layer 516. Generally, a thickness of the second metal layer 515 is slightly greater than a thickness of the first metal layer 514, and a thickness of the dielectric layer 516 is equal to a first passivation layer 518a, such that a height h of the surrounding area of the array substrate is less than the maximum height H of the transition area 511 of the array substrate.

As shown in FIG. 7, a display panel 600 according to another embodiment is substantially the same as the display panel 100. The difference between the display panel 600 and the display panel 100 is that, a transfer region 611 of an array substrate includes a substrate 612, a first metal layer 614 provided on the substrate 612, a first inorganic film layer provided on a part of a surface of the first metal layer 614, a third metal layer 613 provided on the first inorganic film layer, a third inorganic film layer provided on the third metal layer 613, and a transparent metal layer 619 provided on the remaining surface of the first metal layer 614 and the third inorganic film layer. The transparent metal layer 619 is electrically connected to the first metal layer 614 and the third metal layer 613. The first metal layer 614 is a gate layer, and the third metal layer 613 is a source/drain layer.

A surrounding area of the array substrate includes the substrate 612, a second metal layer 615 provided on the substrate, and a second inorganic film layer provided on the second metal layer 615. The second metal layer 615 is a source/drain layer.

More specifically, the first inorganic film layer is a dielectric layer 616. The second inorganic film layer is a second passivation layer 618b. The third inorganic film layer is a first passivation layer 618a.

Compared with the transition area 611 of the array substrate, the surrounding area of the array substrate doer not have the first metal layer 614, the dielectric layer 616 and the transparent metal layer 619, and thus a height h of the surrounding area of the array substrate is less than the maximum height Hof the transition area 611 of the array substrate.

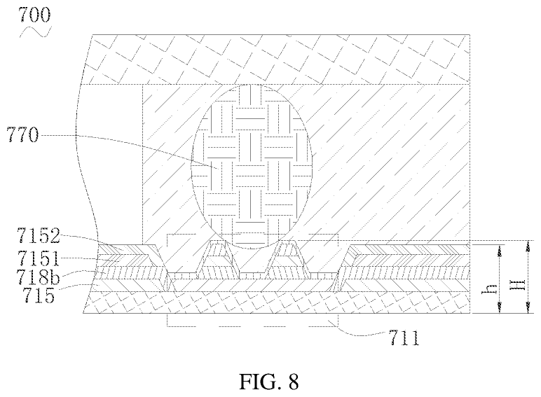

As shown in FIG. 8, a display panel 700 according to another embodiment is substantially the same as the display panel 600. The difference between the display panel 700 and the display panel 600 is that, a surrounding area of an array substrate further includes a fourth metal layer 7151 provided on a second inorganic film layer 718b, and a fourth inorganic film layer 7152 provided on the fourth metal layer 7151.

Compared with a transition area 711 of the array substrate, the surrounding area of the array substrate does not have a transparent metal layer, and thus a height h of the surrounding area of the array substrate is less than the maximum height H of the transition area 711 of the array substrate.

Compared with the display panel 600, the fourth metal layer 7151 and the fourth inorganic film layer 7152 of the display panel 700 can reduce a height difference between the transition area 711 and the surrounding area of the array substrate. Therefore, even if a conductive rubber ball 770 deviates, the conductive rubber ball 770a can relatively stably abut against the common wiring on the array substrate and a common electrode on a color filter substrate.

Optionally, the fourth metal layer 7151 is electrically connected to a second metal layer 715, such that static electricity generated by the fourth metal layer 7151 and the second metal layer 715 can be transferred to each other, thereby further alleviating the electrostatic breakdown phenomenon caused by the large-area static electricity accumulation on the single metal layer.

In other embodiments, the surrounding area of the array substrate further includes a transparent metal layer provided on the second inorganic film layer 718b or the fourth inorganic film layer 7152 to reduce the height difference between the transition area and the surrounding area of the array substrate.

It should be understood that the structure of the display panel is not limited to the above-mentioned structures, as long as it can be satisfied that the height of the surrounding area of the array substrate is less than the maximum height of the transition area 711 of the array substrate.

In an embodiment, the surrounding area of the array substrate is an area of the non-display area of the array substrate excluding the transition area. As such, the structure of the non-display area of the array substrate can be more simple, and the manufacturing process of the array substrate can be more simple.

In an embodiment, a display device is further provided, which includes the above-mentioned display panel.

In the above display device, the height of the surrounding area of the array substrate is less than the maximum height of the transition area of the array substrate, and thus even if the conductive rubber ball deviates from the transition area, the distance between the array substrate and the color filter substrate is not increased, thereby avoiding light leakage.

Although the respective embodiments have been described one by one, it shall be appreciated that the respective embodiments will not be isolated. Those skilled in the art can apparently appreciate upon reading the disclosure of this application that the respective technical features involved in the respective embodiments can be combined arbitrarily between the respective embodiments as long as they have no collision with each other. Of course, the respective technical features mentioned in the same embodiment can also be combined arbitrarily as long as they have no collision with each other.

Although the application is illustrated and described herein with reference to specific embodiments, the application is not intended to be limited to the details shown. Rather, various modifications may be made in the details within the scope and range of equivalents of the claims and without departing from the application. Therefore, the protection scope of the present application shall be subject to the protection scope of the appended claims.

What is claimed is:

1. A display panel, comprising:
an array substrate provided with a common wiring thereon, the array substrate comprising a display area and a non-display area surrounding the display area;
a color filter substrate aligned with the array substrate, the color filter substrate being provided with a common electrode thereon corresponding to the common wiring;
a sealant provided between the array substrate and the color filter substrate, the sealant, the array substrate, and the color filter substrate enclosing a liquid crystal accommodating space; and
a conductive rubber ball embedded in the sealant to conduct the common wiring to the common electrode;
wherein the non-display area of the array substrate comprises a transition area corresponding to the conductive rubber ball and a surrounding area surrounding the transition area;
wherein taking a surface of the array substrate away from the color filter substrate as a reference, a height of the surrounding area of the array substrate is less than the maximum height of the transition area of the array substrate.

2. The display panel according to claim 1, wherein the transition area comprises a substrate, a first metal layer provided on the substrate, a first inorganic film layer provided on a part of a surface of the first metal layer, and a transparent metal layer provided on the remaining surface of the first metal layer and the first inorganic film layer, the transparent metal layer is electrically connected to the first metal layer;
the surrounding area of the array substrate comprises the substrate, a second metal layer provided on the substrate, and a second inorganic film layer provided on the second metal layer, the second metal layer is electrically connected to the first metal layer;
wherein one of the first metal layer and the second metal layer is a gate layer, and the other one thereof is a source layer or a drain layer.

3. The display panel according to claim 2, wherein the first metal layer is the gate layer, the second metal layer is the source layer or the drain layer.

4. The display panel according to claim 3, wherein the first inorganic film layer comprises a dielectric layer and a first passivation layer sequentially provided on the first metal layer, the second inorganic film layer comprises a second passivation layer provided on the second metal layer.

5. The display panel according to claim 3, wherein the first inorganic film layer comprises a dielectric layer provided on the first metal layer, the second inorganic film layer comprises a second passivation layer provided on the second metal layer.

6. The display panel according to claim 3, wherein the first inorganic film layer comprises a first passivation layer provided on the first metal layer, the second inorganic film layer comprises a second passivation layer provided on the second metal layer.

7. The display panel according to claim 2, wherein the first metal layer is the source layer or the drain layer, the second metal layer is the gate layer.

8. The display panel according to claim 7, wherein the first inorganic film layer comprises a first passivation layer provided on the first metal layer, the second inorganic film layer comprises a second passivation layer provided on the second metal layer.

9. The display panel according to claim 7, wherein the first inorganic film layer comprises a first passivation layer provided on the first metal layer, the second inorganic film layer comprises a dielectric layer provided on the second metal layer.

10. The display panel according to claim 1, wherein the transition area comprises a substrate, a first metal layer provided on the substrate, a first inorganic film layer provided on a part of a surface of the first metal layer, a third metal layer provided on the first inorganic film layer, a third inorganic film layer provided on the third metal layer, and a transparent metal layer provided on the remaining surface of the first metal layer and the third inorganic film layer; the transparent metal layer is electrically connected to the first metal layer and the third metal layer, the first metal layer is a gate layer, and the third metal layer is a source layer or a drain layer;
the surrounding area comprises the substrate, a second metal layer provided on the substrate, and a second inorganic film layer provided on the second metal layer, the second metal layer is a source layer or a drain layer.

11. The display panel according to claim 10, wherein the first inorganic film layer is a dielectric layer, the second inorganic film layer is a second passivation layer, and the third inorganic film layer is a first passivation layer.

12. The display panel according to claim 10, wherein the surrounding area further comprises a fourth metal layer provided on a second inorganic film layer, and a fourth inorganic film layer provided on the fourth metal layer.

13. The display panel according to claim 12, wherein the fourth metal layer is electronically connected to the second metal layer.

14. The display panel according to claim 12, wherein the surrounding area further comprises a transparent metal layer provided on the second inorganic film layer or the fourth inorganic film layer.

15. The display panel according to claim 1, wherein the surrounding area is an area of the non-display area excluding the transition area.

16. A display device, comprising the display panel according to claim 1.
